(19) United States
(12) Patent Application Publication
(10) Pub. No.: US 2026/0156975 A1
(43) Pub. Date: Jun. 4, 2026

(54) OPTOELECTRONIC SEMICONDUCTOR ELEMENT

(71) Applicant: Industrial Technology Research Institute, Hsinchu (TW)

(72) Inventor: Hsueh-Hsing Liu, Taipei City (TW)

(73) Assignee: Industrial Technology Research Institute, Hsinchu (TW)

(21) Appl. No.: 18/967,659

(22) Filed: Dec. 4, 2024

(51) Int. Cl. H10H 20/814; H10H 20/812; H10H 20/818; H10H 20/825

(52) U.S. Cl. CPC H10H 20/8142; H10H 20/812; H10H 20/818; H10H 20/825

(57) ABSTRACT

An optoelectronic semiconductor element includes a substrate, a first N-type Bragg reflector, an N-type gallium nitride layer, a tunnel junction layer, a P-type gallium nitride layer, a light emitting layer, and a second N-type Bragg reflector sequentially stacked. The first N-type Bragg reflector has a first reflectivity, the second N-type Bragg reflector has a second reflectivity, both the first reflectivity and the second reflectivity are greater than or equal to 90%, and the first reflectivity is different from the second reflectivity.

### TECHNICAL FIELD

The disclosure relates to a semiconductor element, and in particular to an optoelectronic semiconductor element.

### RELATED ART

In optoelectronic semiconductor elements, resonant cavity light emitting diodes (RC LED) or vertical cavity surface emitting lasers (VCSEL) are elements where the light emitting layer or gain medium is disposed between two reflectors (such as a distributed Bragg reflector, DBR), and the resonance effect is used to allow merely light beams in a specific wavelength range to resonate and emit from the optoelectronic semiconductor elements, which can effectively generate light beams with narrow wavelength and improve luminous efficiency.

However, it is difficult to grow DBR structures in gallium nitride (GaN) materials. If the DBR structure is to match the lattice of GaN, then the difference in refractive index between the two is small, resulting in poor reflectivity of the DBR structure and a higher resistance, which affects the electrical and optical performance of the diode. On the other hand, if the difference in refractive index between the DBR structure and GaN is large, then it may easily cause a mismatch in lattice constants between the two, leading to defects or even cracks during the epitaxial growth of the DBR structure, making it difficult to improve the production yield.

### SUMMARY

The disclosure provides an optoelectronic semiconductor element that can improve the epitaxial quality of the Bragg reflector, increase the production yield of the optoelectronic semiconductor element, and have good optical effects and good conductivity.

An embodiment of the disclosure provides an optoelectronic semiconductor element, which includes a substrate, a first N-type Bragg reflector, an N-type gallium nitride layer, a tunnel junction layer, a P-type gallium nitride layer, a light emitting layer, and a second N-type Bragg reflector sequentially stacked. The first N-type Bragg reflector has a first reflectivity, the second N-type Bragg reflector has a second reflectivity, both the first reflectivity and the second reflectivity are greater than or equal to 90%, and the first reflectivity is different from the second reflectivity.

An embodiment of the disclosure provides an optoelectronic semiconductor element, which includes a substrate, a first N-type Bragg reflector, an N-type gallium nitride layer, a light emitting layer, a P-type gallium nitride layer, a tunnel junction layer, and a second N-type Bragg reflector sequentially stacked. The first N-type Bragg reflector has a first reflectivity, the second N-type Bragg reflector has a second reflectivity, both the first reflectivity and the second reflectivity are greater than or equal to 90%, and the first reflectivity is different from the second reflectivity.

Based on the above, the optoelectronic semiconductor element of the disclosure may directly grow the two upper and lower layers of the DBR structure during the epitaxial growth fabrication process, and the DBR structure is an N-type semiconductor material that is easy to grow. In addition to reducing manufacturing steps, the DBR structure can also be directly manufactured using the general light emitting diode process, and the technology is mature and the production yield is good. In addition, the optoelectronic semiconductor element uses gallium nitride material. Since the epitaxial structure of gallium nitride may have a reverse polarization electric field, when the optoelectronic semiconductor element is energized, the reverse polarization electric field can reduce the chance of carrier overflow, thereby improving the luminous efficiency of the light emitting diode. Further, since the two layers of the DBR structure are made of N-type semiconductor materials, both the cathode electrode and the anode electrode merely need to be made of one n-type metal, thereby further simplifying the manufacturing process.

In order to make the disclosure more comprehensible, embodiments are given below and described in detail with the accompanying drawings.

### BRIEF DESCRIPTION OF THE DRAWINGS

FIG. 1 is a schematic cross-sectional view of an optoelectronic semiconductor element according to an embodiment of the disclosure.

FIG. 2A is a schematic cross-sectional view of a first N-type Bragg reflector of the embodiment in FIG. 1.

FIG. 2B is a schematic cross-sectional view of a tunnel junction layer of the embodiment in FIG. 1.

FIG. 3 is a schematic cross-sectional view of the optoelectronic semiconductor element according to an embodiment of the disclosure.

FIG. 4 is a schematic cross-sectional view of the optoelectronic semiconductor element according to an embodiment of the disclosure.

FIG. 5 is a schematic cross-sectional view of the optoelectronic semiconductor element according to an embodiment of the disclosure.

### DESCRIPTION OF EMBODIMENTS

The direction terms mentioned herein, such as: “upper”, “lower”, “front”, “back”, “left”, “right”, are merely referring to the direction of the accompanying drawings. Therefore, the direction terms used are for illustrative purposes and not for limiting the disclosure. In the drawings, each drawing illustrates the general characteristics of methods, structures, and/or materials used in particular embodiments. However, the drawings should not be interpreted as defining or limiting the scope or nature encompassed by the embodiments. For example, the relative sizes, thicknesses, and positions of various film layers, regions, and/or structures may be reduced or enlarged for clarity.

As used herein, “about,” “approximately,” “substantially,” or “essentially” includes the specified value and an average within an acceptable range of deviations from the particular value as determined by persons of ordinary skill in the art, taking into account the specific amount of measurement and the measurement-related errors (that is, the limitations of the measurement system). For example, “about” may mean within one or more standard deviations of the stated value, or within ±30%, ±20%, ±15%, ±10%, ±5%, for example. Furthermore, the terms “about,” “approximately,” “substantially,” or “essentially” used herein may be based on measurement properties, cutting properties, or other properties to select a more acceptable deviation range or standard deviation, and do not require a single standard deviation to apply to all properties.

In the drawings, each drawing illustrates the general characteristics of methods, structures, and/or materials used in particular exemplary embodiments. However, the drawings should not be interpreted as defining or limiting the scope or nature encompassed by the exemplary embodiments. For example, for clarity, the relative sizes, thicknesses, and positions of various film layers, regions, and/or structures may be reduced or enlarged, and/or some components or film layers may be omitted.

It will be understood that when an element such as a layer, film, region, or substrate is referred to as being “on” another element or “connected to” another element, it may be directly on or connected to the other element, or intermediate elements may also be present. In contrast, when an element is referred to as being “directly on another element” or “directly connected to” another element, there are no intermediate elements present. As used herein, “connected” may refer to a physical and/or electrical connection. Furthermore, “electrical connection” may mean the presence of other components between the two components.

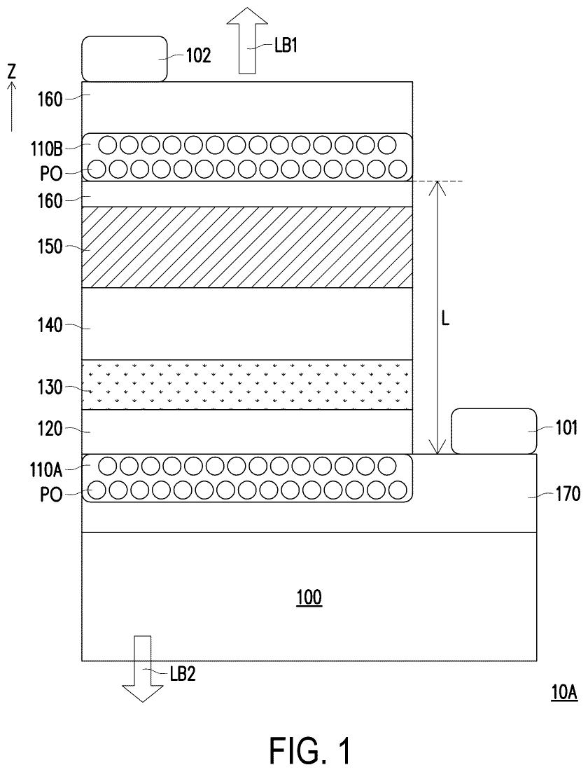

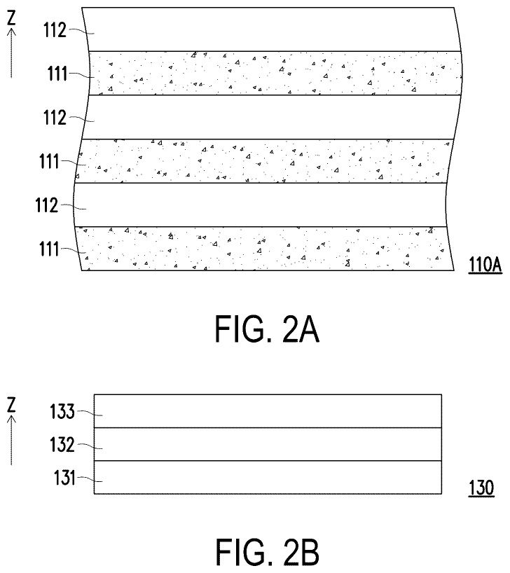

FIG. 1 is a schematic cross-sectional view of an optoelectronic semiconductor element according to an embodiment of the disclosure. FIG. 2A is a schematic cross-sectional view of a first N-type Bragg reflector of the embodiment in FIG. 1. FIG. 2B is a schematic cross-sectional view of a tunnel junction layer of the embodiment in FIG. 1. Referring to FIG. 1 first, an optoelectronic semiconductor element 10A includes a substrate 100, a first N-type Bragg reflector 110A, an N-type gallium nitride layer 120, a tunnel junction layer 130, a P-type gallium nitride layer 140, a light emitting layer 150, and a second N-type Bragg reflector 110B stacked sequentially along a direction Z. On the other hand, the optoelectronic semiconductor element 10A may further include a first contact layer 170 disposed between the substrate 100 and the first N-type Bragg reflector 110A; may include a second contact layer 160, in which the second N-type Bragg reflector 110B is disposed in the second contact layer 160; and may include a first electrode 101 disposed on the first contact layer 170, and a second electrode 102 disposed on the second contact layer 160. In this disclosure, the direction Z may represent the stacking direction or epitaxial direction of each layer, or may represent the normal direction of the substrate 100, but the disclosure is not limited thereto.

In this embodiment, the substrate 100 may be a growth substrate of the optoelectronic semiconductor element 10A. Each of the semiconductor layers and electrodes may be epitaxially grown on the substrate 100 sequentially using physical vapor deposition (PVD), chemical vapor deposition (CVD), or atomic layer deposition (ALD), and then fabricated on the substrate 100 using a photolithography process and an etching process, but the disclosure is not limited thereto. The material of the substrate 100 may be sapphire substrate, silicon carbide substrate (SiC), or silicon substrate (Si), but the disclosure is not limited thereto. The substrate 100 may be a non-patterned sapphire substrate or a patterned sapphire substrate. Furthermore, the patterned substrate may also refer to the surface formed when being separated from the sapphire substrate using a laser lift-off process, and at this point, the patterned substrate may also have a similar cross-sectional shape, but the disclosure is not limited thereto.

Referring to FIG. 1 together with FIG. 2A, the first N-type Bragg reflector 110A is disposed on the substrate 100, and the second N-type Bragg reflector 110B is disposed on the light emitting layer 150. It is worth mentioning that the first N-type Bragg reflector 110A may have a first reflectivity, the second N-type Bragg reflector 110B may have a second reflectivity, both the first reflectivity and the second reflectivity are greater than or equal to 90%, and the first reflectivity is different from the second reflectivity.

Specifically, the first N-type Bragg reflector 110A and the second N-type Bragg reflector 110B may be formed by multiple layers of semiconductor materials with different refractive indices arranged in a periodic manner. For example, the first N-type Bragg reflector 110A may include multiple layers of first gallium nitride layer 111 and multiple layers of second gallium nitride layer 112. The first gallium nitride layer 111 and the multiple layers of second gallium nitride layer 112 may have different refractive indices, and the multiple layers of first gallium nitride layer 111 and the multiple layers of second gallium nitride layer 112 may be arranged alternately in the direction Z to form a periodic structure with alternating refractive index changes. For example, in the first gallium nitride layer 111 and the second gallium nitride layer 112 with a periodic distribution and both N-type doped, the doping concentration of the second gallium nitride layer 112 may be greater than the doping concentration of the first gallium nitride layer 111. In some embodiments, the first gallium nitride layer 111 may be an intrinsic semiconductor or pure gallium nitride without doped elements, and the second gallium nitride layer 112 may be a highly-concentrated doped N-type gallium nitride material. In some embodiments, the N-type element doped in the second gallium nitride layer 112 may be silicon (Si) atoms or germanium (Ge) atoms, and the doping concentration of the N-type dopant atoms may be greater than 10¹⁹ (1/cm³), but the disclosure is not limited thereto. It is worth mentioning that in FIG. 2A, the first N-type Bragg reflector 110A is taken as an example for illustrative purposes, but the material or composition of the second N-type Bragg reflector 110B may be the same as the material or composition of the first N-type Bragg reflector 110A, and the disclosure is not limited thereto.

The N-type gallium nitride layer 120 is disposed on the first N-type Bragg reflector 110A, the tunnel junction layer 130 is disposed on the N-type gallium nitride layer 120, and the P-type gallium nitride layer 140 is disposed on the tunnel junction layer 130. From another perspective, the tunnel junction layer 130 is disposed between the N-type gallium nitride layer 120 and the P-type gallium nitride layer 140. The N-type gallium nitride layer 120 may be, for example, a gallium nitride semiconductor doped with Si atoms. In some embodiments, the carrier doping concentration of the N-type gallium nitride layer 120 may be 5*10¹⁸ (1/cm³). The P-type gallium nitride layer 140 may be, for example, a gallium nitride semiconductor doped with Mg atoms. In some embodiments, the carrier doping concentration of the P-type gallium nitride layer 140 may be 1.2*10¹⁸ (1/cm³). The tunnel junction layer 130 may ensure that there is no built-in electric field between the N-type gallium nitride layer 120 and the P-type gallium nitride layer 140, making it easier for the current to pass through the optoelectronic semiconductor element 10A, and allowing both sides opposite to each other of the light emitting layer 150 to have the N-type semiconductor material.

Next, referring to FIG. 1 together with FIG. 2B, the tunnel junction layer 130 may further include an N-type heavily doped layer 131, a low energy material layer 132, and a P-type heavily doped layer 133 stacked along the direction Z. In some embodiments, the doping concentration of the N-type heavily doped layer 131 may be 5*10¹⁹ (1/cm³), and the thickness may be substantially 5 nm. The doping concentration of the P-type heavily doped layer 133 may be 3*10¹⁹ (1/cm³), and the thickness may be substantially 5 nm. In some embodiments, the material of the low energy material layer 132 may include indium gallium aluminum nitride (AlGaNInN) or aluminum metal. The thickness of the low energy material layer 132 may be thinner, such as substantially 3 nm, to increase carrier tunneling efficiency, but the disclosure is not limited thereto.

The light emitting layer 150 is disposed on the P-type gallium nitride layer 140, the second contact layer 160 is disposed on the light emitting layer 150, and the second N-type Bragg reflector 110B is disposed on the second contact layer 160. The second contact layer 160 is an N-type doped gallium nitride layer, and the light emitting layer 150 may be a multiple quantum well (MQW) structure or a quantum dot, and the disclosure is not limited thereto. By applying an external electric field (for example, the direction of the electric field is the direction Z) to the optoelectronic semiconductor element 10A, the electrons provided by the second contact layer 160 and the holes provided by the P-type gallium nitride layer 140 recombine in the light emitting layer 150 to emit light beams, such as emitting a first light beam LB1 and a second light beam LB2.

On the other hand, the first electrode 101 is disposed on the first contact layer 170 and is electrically coupled to the first contact layer 170. In this embodiment, the first electrode 101 may serve as an anode. The second electrode 102 is disposed on the second contact layer 160 and is electrically coupled to the second contact layer 160. In this embodiment, the second electrode 102 may serve as a cathode, but the disclosure is not limited thereto. The first contact layer 170 may be, for example, used as a buffer layer, and the material is N-type doped gallium nitride. The materials of the first electrode 101 and the second electrode 102 may include metal materials, alloy materials, or combinations thereof that are suitable for forming an ohmic contact with N-type gallium nitride, but the disclosure is not limited thereto. Since both the first electrode 101 and the second electrode 102 may be made of materials suitable for forming the ohmic contact with the N-type gallium nitride material, the first electrode 101 and the second electrode 102 may be fabricated in the same process, thereby reducing manufacturing steps and indirectly improving the yield.

Based on the above, through the disposition of the tunnel junction layer 130 in the optoelectronic semiconductor element 10A, there may be N-type gallium nitride semiconductor layers (such as the N-type gallium nitride layer 120 and the second contact layer 160) on both sides opposite to each other of the light emitting layer 150. Moreover, the first N-type Bragg reflector 110A and the second N-type Bragg reflector 110B are further disposed on the two opposite sides. Due to the characteristics of the N-type semiconductor material being easy to epitaxially grow and fabricate, the process yield of the first N-type Bragg reflector 110A and the second N-type Bragg reflector 110B can be improved. In other words, it is easy to produce the first N-type Bragg reflector 110A and the second N-type Bragg reflector 110B with high reflectivity (for example, both may reach more than 90%, or more than 99%), so the optoelectronic semiconductor element 10A has a relatively good optical performance. For example, the optical resonance effect of the optoelectronic semiconductor element 10A is improved, providing light beams with narrower frequencies and higher coherence. When the optoelectronic semiconductor element 10A is applied to VCSEL, the optical performance is also relatively good.

On the other hand, due to the lattice structure of the gallium nitride material, a polarization electric field may be generated in the epitaxial direction, such as toward the negative Z direction in FIG. 1. When the optoelectronic semiconductor element 10A is energized, the direction of the polarization electric field is opposite to the direction (for example, the direction Z) of the external electric field of the optoelectronic semiconductor element 10A, so the electron mobility in the optoelectronic semiconductor element 10A may be slowed down. Since electron mobility is greater than hole mobility, the inconsistency between the electron mobility and hole mobility causes carrier overflow, thereby reducing the probability of electrons and holes recombining in the light emitting layer 150. On the contrary, this embodiment slows down the electron mobility in the optoelectronic semiconductor element 10A, which can increase the probability of electrons and holes recombining in the light emitting layer 150, so that the luminous efficiency of the optoelectronic semiconductor element 10A can be improved.

On the other hand, in this embodiment, the reflectivity of the first N-type Bragg reflector 110A may be smaller than the reflectivity of the second N-type Bragg reflector 110B. When the light beam emitted from the light emitting layer 150 oscillates between the first N-type Bragg reflector 110A and the second N-type Bragg reflector 110B, light beams with specific wavelengths may exit the optoelectronic semiconductor element 10A via a side of the reflector with lower reflectivity. For example, in this embodiment, since the reflectivity of the first N-type Bragg reflector 110A is lower, the intensity of the second light beam LB2 emitted from the first N-type Bragg reflector 110A is greater than the intensity of the first light beam LB1 emitted from the second N-type Bragg reflector 110B. In other words, the light emission direction of the optoelectronic semiconductor element 10A may be the opposite direction of the direction Z, but the disclosure is not limited thereto. In other embodiments, the reflectivity of the first N-type Bragg reflector 110A may be greater than the reflectivity of the second N-type Bragg reflector 110B. Therefore, the intensity of the second light beam LB2 emitted from the first N-type Bragg reflector 110A may be smaller than the intensity of the first light beam LB1 emitted from the second N-type Bragg reflector 110B. In other words, the light emission direction of the optoelectronic semiconductor element 10A may also be the direction Z.

On the other hand, in order to further improve the resonance condition of the resonant cavity, the length of the resonant cavity in the optoelectronic semiconductor element 10A may be a positive integer multiple of half the wavelength of the light beam emitted from the light emitting layer 150. In detail, there is a distance L between the upper surface of the first N-type Bragg reflector 110A and the lower surface of the second N-type Bragg reflector 110B as the length of the resonant cavity, and the following formula is satisfied: λ=2*L /m, in which λ is the wavelength of the light beam emitted from the light emitting layer 150 in the resonant cavity, and m is a positive integer. From another perspective, the total thickness of the N-type gallium nitride layer 120, the tunnel junction layer 130, the P-type gallium nitride layer 140, the light emitting layer 150, and the second contact layer 160 in the direction Z may be regarded as the length of the resonant cavity (that is, the distance L). λ may be a ratio of the theoretical wavelength of the peak of the light beam emitted from the light emitting layer 150 and the average refractive index in the resonant cavity.

Please refer to FIG. 1 and FIG. 2A again. It is worth mentioning that in this embodiment, the first N-type Bragg reflector 110A and the second N-type Bragg reflector 110B may both be nanoporous Bragg reflectors. In detail, during the fabrication process of the first gallium nitride layer 111 and the second gallium nitride layer 112, etching may be performed on the first gallium nitride layer 111 and the second gallium nitride layer 112. Since the doping concentration of the second gallium nitride layer 112 is greater than the doping concentration of the first gallium nitride layer 111, or the first gallium nitride layer 111 is an intrinsic semiconductor, during the etching process, the second gallium nitride layer 112 with a high doping concentration may form a material of multiple nanometer-sized pores, such as multiple pores PO schematically shown in FIG. 1. In this way, the first gallium nitride layer 111 and the second gallium nitride layer 112 may have a larger refractive index difference, so that the first N-type Bragg reflector 110A and the second N-type Bragg reflector 110B are both conductive and with high reflectivity. Moreover, the disposition of the first N-type Bragg reflector 110A and the second N-type Bragg reflector 110B may be completed simultaneously during the epitaxial growth process of the optoelectronic semiconductor element 10A. There is no need to add additional processes through subsequent processes (such as coating), thereby improving production yield and reducing cost.

Other embodiments will be described below to illustrate the disclosure in detail, in which the same components will be marked with the same reference signs, and the description of the same technical content will be omitted. For the omitted part, reference may be made to the foregoing embodiments, so details will not be repeated here.

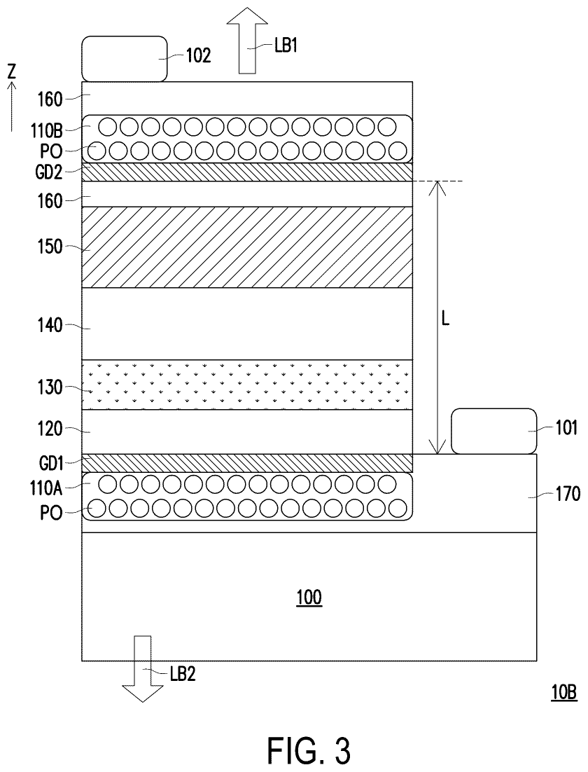

FIG. 3 is a schematic cross-sectional view of the optoelectronic semiconductor element according to an embodiment of the disclosure. Referring to FIG. 3, an optoelectronic semiconductor element 10B of this embodiment is similar to the optoelectronic semiconductor element 10A, and the main difference is that the optoelectronic semiconductor element 10B further includes a first refractive index gradient layer GD1 disposed between the first N-type Bragg reflector 110A and the light emitting layer between 150, and a second refractive index gradient layer GD2 disposed between the second N-type Bragg reflector 110B and the light emitting layer 150.

The first refractive index gradient layer GD1 and the second refractive index gradient layer GD2 may be formed by stacking unetched gallium nitride. Alternatively, different second gallium nitride layers 112 are allowed to have different porosity, or the size of the pores PO of different second gallium nitride layers 112 are made different, in order to form the first refractive index gradient layer GD1 and the second refractive index gradient layer GD2. For example, in the direction Z, the plurality of second gallium nitride layers 112 in the first N-type Bragg reflector 110A may have gradient porosity. For example, the concentration or type of the etching solution may be adjusted so that in the direction Z, the size of the pores PO of different second gallium nitride layers 112 gradually increase to form a gradient change in refractive index, thereby fewer layers of first gallium nitride layer 111 and second gallium nitride layer 112 may be used to achieve an expected reflectivity, thereby further reducing manufacturing steps, improving production yield, and reducing production costs.

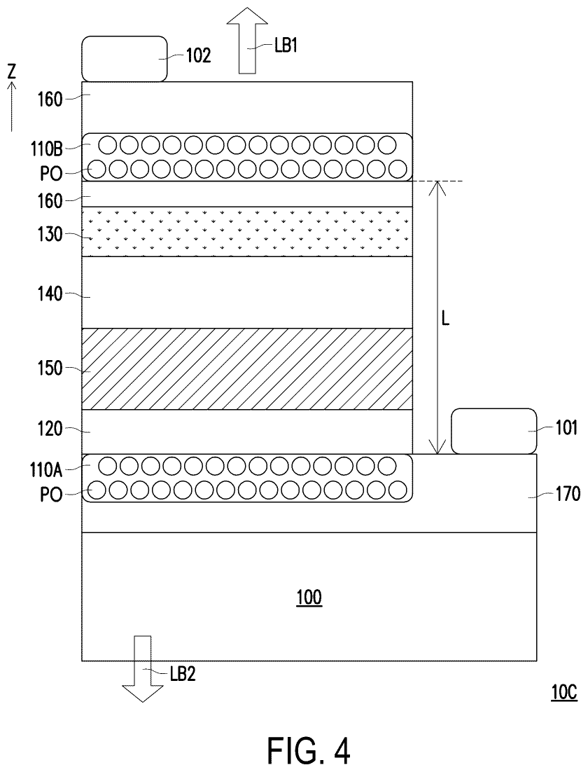

FIG. 4 is a schematic cross-sectional view of the optoelectronic semiconductor element according to an embodiment of the disclosure. Referring to FIG. 4, an optoelectronic semiconductor element 10C of this embodiment is similar to the optoelectronic semiconductor element 10A, and the main difference is that the positions of the light emitting layer 150 and the tunnel junction layer 130 of the optoelectronic semiconductor element 10C are exchanged with each other.

In detail, in this embodiment, the tunnel junction layer 130 is disposed on the P-type gallium nitride layer 140, and is disposed between the second N-type Bragg reflector 110B and the P-type gallium nitride layer 140, while the light emitting layer 150 is disposed on the N-type gallium nitride layer 120, and is disposed between the P-type gallium nitride layer 140 and the N-type gallium nitride layer 120. In this way, the optoelectronic semiconductor element 10C may also have technical effects similar to the optoelectronic semiconductor element 10A. For related content, reference may be made to the foregoing paragraphs, so details will not be repeated here.

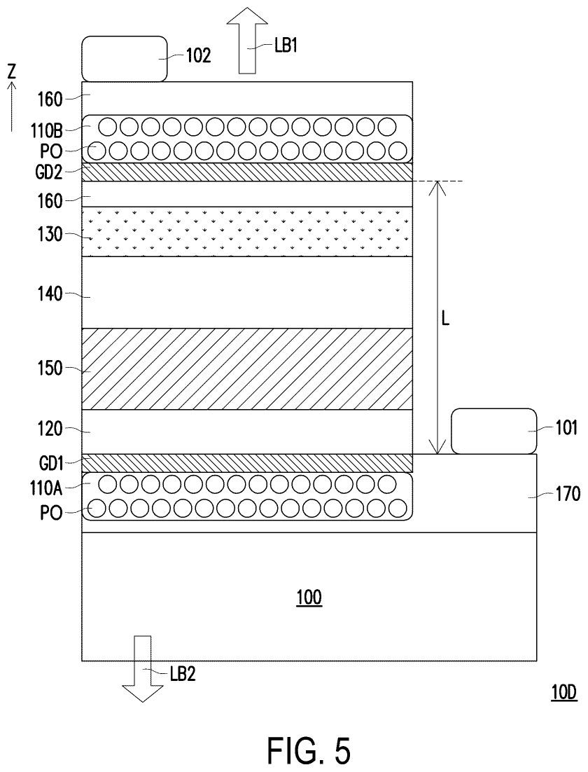

FIG. 5 is a schematic cross-sectional view of the optoelectronic semiconductor element according to an embodiment of the disclosure. Referring to FIG. 5, an optoelectronic semiconductor element 10D of this embodiment is similar to the optoelectronic semiconductor element 10C, and the main difference is that the optoelectronic semiconductor element 10D further includes the first refractive index gradient layer GD1 disposed between the first N-type Bragg reflector 110A and the light emitting layer 150, and the second refractive index gradient layer GD2 disposed between the second N-type Bragg reflector 110B and the light emitting layer 150. Through the disposition of the first refractive index gradient layer GD1 and the second refractive index gradient layer GD2, the optoelectronic semiconductor element 10D may also reduce the number of stacking layers of first gallium nitride layer 111 and second gallium nitride layer 112 in the first N-type Bragg reflector 110A and the second N-type Bragg reflector 110B, thereby achieving the expected high reflectivity. Therefore, the optoelectronic semiconductor element 10D can also have advantages and effects similar to the optoelectronic semiconductor element 10C and the optoelectronic semiconductor element 10B. For related content, reference may be made to the foregoing paragraphs, so details will not be repeated here.

In summary, the optoelectronic semiconductor element in the disclosure may directly grow the two upper and lower layers of the DBR structure during the epitaxial growth fabrication process, and the DBR structure is an N-type semiconductor material with high conductivity. In addition to reducing manufacturing steps, the conventional light emitting diode process may also be used, and the technology is mature and the production yield is good. In addition, the optoelectronic semiconductor element uses gallium nitride material. Since the epitaxial structure of gallium nitride may have a reverse polarization electric field, when the optoelectronic semiconductor element is energized, the reverse polarization electric field can reduce the chance of carrier overflow, thereby improving the luminous efficiency of the light emitting diode. Further, since the two layers of the DBR structure are made of N-type semiconductor materials, both the cathode electrode and the anode electrode merely need to be made of one n-type metal, thereby further simplifying the manufacturing process.

Although the disclosure has been disclosed in the embodiments, the embodiments are not intended to limit the disclosure. Persons with ordinary knowledge in the relevant technical field may make changes and modifications without departing from the spirit and scope of the disclosure. Therefore, the protection scope of the disclosure shall be determined by the appended claims and the equivalent scope thereof.

What is claimed is:

1. An optoelectronic semiconductor element, comprising:
a substrate;
a first N-type Bragg reflector disposed on the substrate, wherein the first N-type Bragg reflector has a first reflectivity;
an N-type gallium nitride layer disposed on the first N-type Bragg reflector;
a tunnel junction layer disposed on the N-type gallium nitride layer;
a P-type gallium nitride layer disposed on the tunnel junction layer;
a light emitting layer disposed on the P-type gallium nitride layer; and
a second N-type Bragg reflector disposed on the light emitting layer, wherein the second N-type Bragg reflector has a second reflectivity,
the first reflectivity and the second reflectivity are both greater than or equal to 90%, and the first reflectivity is different from the second reflectivity.

2. The optoelectronic semiconductor element as claimed in claim 1, wherein the first reflectivity is smaller than the second reflectivity.

3. The optoelectronic semiconductor element as claimed in claim 2, wherein an intensity of a light beam emitted from the first N-type Bragg reflector is greater than an intensity of a light beam emitted from the second N-type Bragg reflector.

4. The optoelectronic semiconductor element as claimed in claim 1, wherein the first reflectivity is greater than the second reflectivity.

5. The optoelectronic semiconductor element as claimed in claim 4, wherein an intensity of a light beam emitted from the first N-type Bragg reflector is smaller than an intensity of a light beam emitted from the second N-type Bragg reflector.

6. The optoelectronic semiconductor element as claimed in claim 1, wherein there is a distance between the first N-type Bragg reflector and the second N-type Bragg reflector to form a resonant cavity, and a formula as follows is satisfied: λ=2*L/m, wherein λ is a wavelength of a light beam emitted from the light emitting layer in the resonant cavity, L is the distance, and m is a positive integer.

7. The optoelectronic semiconductor element as claimed in claim 1, wherein the first N-type Bragg reflector comprises at least one first gallium nitride layer and at least one second gallium nitride layer with a periodic distribution, and a doping concentration of the at least one second gallium nitride layer is greater than a doping concentration of the at least one first gallium nitride layer.

8. The optoelectronic semiconductor element as claimed in claim 7, wherein a doping concentration of N-type dopant atoms of the at least one second gallium nitride layer is greater than 10¹⁹ (1/cm³).

9. The optoelectronic semiconductor element as claimed in claim 1, wherein a material of the tunnel junction layer comprises indium gallium aluminum nitride (AlGaNInN).

10. The optoelectronic semiconductor element as claimed in claim 1, wherein a material of the tunnel junction layer comprises aluminum.

11. The optoelectronic semiconductor element as claimed in claim 1, wherein the first N-type Bragg reflector and the second N-type Bragg reflector are nanoporous Bragg reflectors.

12. The optoelectronic semiconductor element as claimed in claim 1, further comprising a refractive index gradient layer disposed between the first N-type Bragg reflector and the light emitting layer.

13. An optoelectronic semiconductor element, comprising:
a substrate;
a first N-type Bragg reflector disposed on the substrate, wherein the first N-type Bragg reflector has a first reflectivity;
an N-type gallium nitride layer disposed on the first N-type Bragg reflector;
a light emitting layer disposed on the N-type gallium nitride layer;
a P-type gallium nitride layer disposed on the light emitting layer;
a tunnel junction layer disposed on the P-type gallium nitride layer; and
a second N-type Bragg reflector disposed on the P-type gallium nitride layer, wherein the second N-type Bragg reflector has a second reflectivity,
the first reflectivity and the second reflectivity are both greater than or equal to 90%, and the first reflectivity is different from the second reflectivity.

14. The optoelectronic semiconductor element as claimed in claim 13, wherein the first reflectivity is smaller than the second reflectivity.

15. The optoelectronic semiconductor element as claimed in claim 14, wherein an intensity of a light beam emitted from the first N-type Bragg reflector is greater than an intensity of a light beam emitted from the second N-type Bragg reflector.

16. The optoelectronic semiconductor element as claimed in claim 13, wherein the first reflectivity is greater than the second reflectivity.

17. The optoelectronic semiconductor element as claimed in claim 16, wherein an intensity of a light beam emitted from the first N-type Bragg reflector is smaller than an intensity of a light beam emitted from the second N-type Bragg reflector.

18. The optoelectronic semiconductor element as claimed in claim 13, wherein the first N-type Bragg reflector comprises at least one first gallium nitride layer and at least one second gallium nitride layer with a periodic distribution, and a doping concentration of the at least one second gallium nitride layer is greater than a doping concentration of the at least one first gallium nitride layer.

19. The optoelectronic semiconductor element as claimed in claim 18, wherein a doping concentration of N-type dopant atoms of the at least one second gallium nitride layer is greater than 10¹⁹ (1/cm³).

20. The optoelectronic semiconductor element as claimed in claim 13, wherein the first N-type Bragg reflector and the second N-type Bragg reflector are nanoporous Bragg reflectors.

21. The optoelectronic semiconductor element as claimed in claim 13, further comprising a refractive index gradient layer disposed between the first N-type Bragg reflector and the light emitting layer.
